(19) United States
(12) Patent Application Publication
(10) Pub. No.: US 2026/0150684 A1
(43) Pub. Date: May 28, 2026

(54) SEMICONDUCTOR DEVICE AND POWER CONVERSION DEVICE

(71) Applicant: Mitsubishi Electric Corporation, Tokyo (JP)

(72) Inventors: Koki OBA, Tokyo (JP); Hiroki TACHIBANA, Tokyo (JP)

(73) Assignee: Mitsubishi Electric Corporation, Tokyo (JP)

(21) Appl. No.: 19/346,439

(22) Filed: Sep. 30, 2025

(30) Foreign Application Priority Data
Nov. 27, 2024 (JP) 2024-205946

(51) Int. Cl. H01L 23/00; H01L 23/31; H02M 7/00; H02P 27/08; H10D 30/01; H10D 30/66; H10D 62/10; H10D 62/832

(52) U.S. Cl. CPC H10W 42/00; H02M 7/003; H10D 30/0291; H10D 30/665; H10D 62/107; H10D 62/8325; H10W 74/147; H02P 27/08

(57) ABSTRACT

A semiconductor device includes a silicon carbide substrate, a field oxide film, an insulation film, and a wiring layer. The silicon carbide substrate includes a first main surface, and a second main surface being an opposite surface of the first main surface. The second main surface includes a cell region, and an outer peripheral region located between the cell region and an outer peripheral edge of the second main surface in plan view. The silicon carbide substrate includes a termination structure and a channel stopper that are formed in the second main surface located in the outer peripheral region in the silicon carbide substrate. The channel stopper is located outside the termination structure in plan view. A conductivity type of the silicon carbide substrate and a conductivity type of the channel stopper are each a first conductivity type.

### CROSS REFERENCE TO RELATED APPLICATIONS

This nonprovisional application is based on Japanese Patent Application No. 2024-205946 filed on Nov. 27, 2024 with the Japan Patent Office, the entire contents of which are hereby incorporated by reference.

### BACKGROUND OF THE INVENTION

### Field of the Invention

The present disclosure relates to a semiconductor device and a power conversion device.

### Description of the Background Art

Japanese Patent Laying-Open No. 2023-85505 describes a semiconductor device. The semiconductor device described in Japanese Patent Laying-Open No. 2023-85505 includes frame wiring located, in plan view, outside a termination structure that is formed of aluminum and ensures a withstand voltage of an active cell. In the semiconductor device described in Japanese Patent Laying-Open No. 2023-85505, an insulation film does not reach the outer peripheral edge of a silicon carbide substrate in plan view and a passivation film is in contact with the silicon carbide substrate.

### SUMMARY OF THE INVENTION

As to the semiconductor device described in Japanese Patent Laying-Open No. 2023-85505, there is a concern about a decrease in reliability, more specifically, in thermal humidity bias (THB) resistance, which is caused by a silicon carbide product generated from the aluminum contained in the frame wiring and the silicon carbide contained in the silicon carbide substrate. The present disclosure provides a semiconductor device with increased THB resistance.

A semiconductor device according to the present disclosure includes a silicon carbide substrate, a field oxide film, an insulation film, and a wiring layer. The silicon carbide substrate includes a first main surface, and a second main surface being an opposite surface of the first main surface. The second main surface includes a cell region, and an outer peripheral region located between the cell region and an outer peripheral edge of the second main surface in plan view. The silicon carbide substrate includes a termination structure and a channel stopper that are formed in the second main surface located in the outer peripheral region in the silicon carbide substrate. The channel stopper is located outside the termination structure in plan view. A conductivity type of the silicon carbide substrate and a conductivity type of the channel stopper are each a first conductivity type. The termination structure has a second conductivity type opposite to the first conductivity type. The field oxide film is formed on the second main surface located in the outer peripheral region so as to overlap the termination structure in plan view and at least partially overlap the channel stopper in plan view. The insulation film is formed over the second main surface so as to cover the field oxide film. The wiring layer is formed on the insulation film so as to be located inside the termination structure in plan view.

The foregoing and other objects, features, aspects, and advantages of the present invention will become apparent from the following detailed description of the present invention, which will be understood in conjunction with the accompanying drawings.

### BRIEF DESCRIPTION OF THE DRAWINGS

FIG. 1 is a plan view of a semiconductor device 100.

FIG. 2 is a cross-sectional view along II-II in FIG. 1.

FIG. 3 is a cross-sectional view along III-III in FIG. 1.

FIG. 4 is a diagram of manufacturing steps of semiconductor device 100.

FIG. 5A is a first cross-sectional view for explaining an impurity diffusion region formation step S2.

FIG. 5B is a second cross-sectional view for explaining impurity diffusion region formation step S2.

FIG. 6 is a cross-sectional view for explaining a field oxide film formation step S3.

FIG. 7 is a cross-sectional view for explaining a gate insulation film formation step S4.

FIG. 8A is a first cross-sectional view for explaining a gate electrode formation step S5.

FIG. 8B is a second cross-sectional view for explaining gate electrode formation step S5.

FIG. 9A is a first cross-sectional view for explaining an insulation film formation step S6.

FIG. 9B is a second cross-sectional view for explaining insulation film formation step S6.

FIG. 10A is a first cross-sectional view for explaining a wiring layer formation step S7.

FIG. 10B is a second cross-sectional view for explaining wiring layer formation step S7.

FIG. 11 is a cross-sectional view for explaining a passivation film formation step S8.

FIG. 12A is a first cross-sectional view for explaining an impurity diffusion region formation step S9.

FIG. 12B is a second cross-sectional view for explaining impurity diffusion region formation step S9.

FIG. 13A is a first cross-sectional view for explaining a drain electrode formation step S10.

FIG. 13B is a second cross-sectional view for explaining drain electrode formation step S10.

FIG. 14 is a cross-sectional view of a semiconductor device 100A.

FIG. 15 is a table indicating the results of a THB resistance test.

FIG. 16 is a cross-sectional view of semiconductor device 100 according to Variation 1.

FIG. 17A is a cross-sectional view of semiconductor device 100 according to Variation 2.

FIG. 17B is a cross-sectional view of semiconductor device 100 according to Variation 3.

FIG. 18 is a cross-sectional view of semiconductor device 100 according to Variation 4.

FIG. 19 is a cross-sectional view of semiconductor device 100 according to Variation 5.

FIG. 20 is an enlarged plan view of semiconductor device 100 according to Variation 6.

FIG. 21 is an enlarged plan view of semiconductor device 100 according to Variation 7.

FIG. 22 is a block diagram illustrating a configuration of a power conversion system to which a power conversion device according to Embodiment 2 is applied.

### DESCRIPTION OF THE PREFERRED EMBODIMENTS

Embodiments of the present disclosure are described in detail with reference to the drawings. In the drawings mentioned below, the same or corresponding portions are given the same reference characters, which are not described repeatedly when overlapping.

### Embodiment 1

A semiconductor device according to Embodiment 1 is described. The semiconductor device according to Embodiment 1 is referred to as semiconductor device 100.

### Configuration of Semiconductor Device 100

A configuration of semiconductor device 100 is described below.

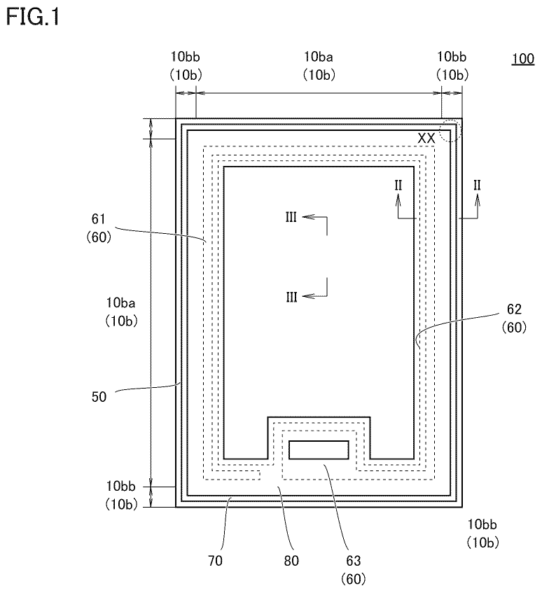

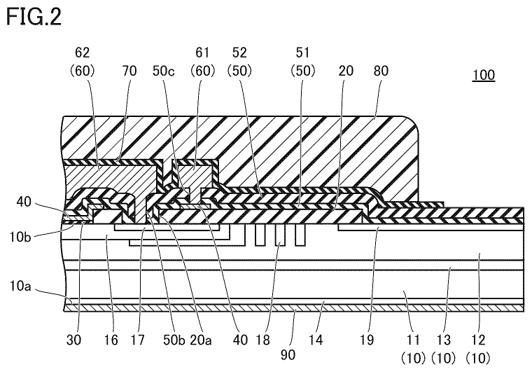

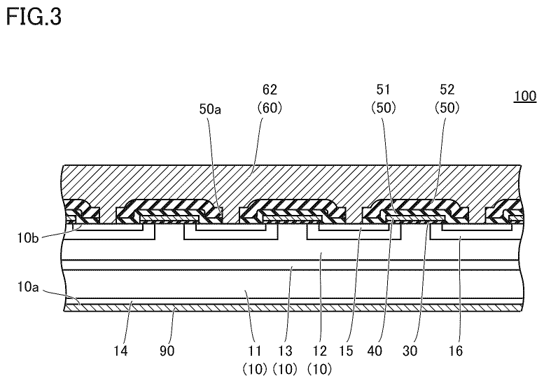

FIG. 1 is a plan view of semiconductor device 100. FIG. 2 is a cross-sectional view along II-II in FIG. 1. FIG. 3 is a cross-sectional view along III-III in FIG. 1. As illustrated in FIGS. 1 to 3, semiconductor device 100 includes a silicon carbide substrate 10, a field oxide film 20, a gate insulation film 30, a gate electrode 40, an insulation film 50, a wiring layer 60, a passivation film 70, a protection film 80, and a drain electrode 90.

Silicon carbide substrate 10 is formed of a single crystal silicon carbide. Silicon carbide substrate 10 includes a main surface 10a and a main surface 10b. Main surface 10a and main surface 10b form respective end surfaces of silicon carbide substrate 10 in its thickness direction. Main surface 10b is an opposite surface of main surface 10a. Main surface 10b includes a cell region 10ba and an outer peripheral region 10bb in plan view. Outer peripheral region 10bb is a region located between cell region 10ba and the outer peripheral edge of main surface 10b.

Silicon carbide substrate 10 includes a foundation layer 11, an epitaxial layer 12, and a buffer layer 13. A lower surface of foundation layer 11 forms main surface 10a. An upper surface of epitaxial layer 12 forms main surface 10b. Epitaxial layer 12 is formed over foundation layer 11 with buffer layer 13 interposed therebetween. The respective conductivity types of foundation layer 11, epitaxial layer 12, and buffer layer 13 are each a first conductivity type. The first conductivity type is, for example, n type.

Silicon carbide substrate 10 includes a drain region 14, a source region 15, and a body region 16. In silicon carbide substrate 10 (foundation layer 11), drain region 14 is formed in main surface 10a. In silicon carbide substrate 10 (epitaxial layer 12), source region 15 is formed in main surface 10b located in cell region 10ba. In silicon carbide substrate 10 (epitaxial layer 12), body region 16 is formed in main surface 10b located in cell region 10ba so as to surround source region 15. The respective conductivity types of drain region 14 and source region 15 are each the first conductivity type. The conductivity type of body region 16 is a second conductivity type. The second conductivity type is, for example, p type.

Silicon carbide substrate 10 further includes a back gate region 17. In silicon carbide substrate 10 (epitaxial layer 12), back gate region 17 is formed in main surface 10b located in cell region 10ba. Back gate region 17 is located in an outer peripheral edge portion of cell region 10ba in plan view. Back gate region 17 is surrounded by body region 16. The conductivity type of back gate region 17 is the second conductivity type.

Silicon carbide substrate 10 further includes a plurality of guard rings 18 and a channel stopper 19. In silicon carbide substrate 10 (epitaxial layer 12), guard ring 18 is formed in main surface 10b located in outer peripheral region 10bb. The plurality of guard rings 18 are arranged at intervals along a direction from the inner peripheral edge of outer peripheral region 10bb toward the outer peripheral edge of outer peripheral region 10bb (the outer peripheral edge of main surface 10b) in plan view. Guard ring 18 is formed in an annular shape in plan view. The conductivity type of guard ring 18 is the second conductivity type. The plurality of guard rings 18 form a termination structure for holding an insulation withstand voltage of semiconductor device 100. In silicon carbide substrate 10 (epitaxial layer 12), channel stopper 19 is formed in main surface 10b located in outer peripheral region 10bb. Channel stopper 19 is located outside the above-mentioned termination structure (the plurality of guard rings 18) in plan view. The conductivity type of channel stopper 19 is the first conductivity type. Channel stopper 19 is formed in an annular shape in plan view.

Field oxide film 20 is formed of, for example, silicon oxide containing neither boron nor phosphorus. Field oxide film 20 is formed on main surface 10b. The inner peripheral edge and the outer peripheral edge of field oxide film 20 are located on cell region 10ba and outer peripheral region 10bb, respectively. That is, field oxide film 20 lies across the boundary between cell region 10ba and outer peripheral region 10bb. Field oxide film 20 overlaps the above-mentioned termination structure (the plurality of guard rings 18) in plan view. Field oxide film 20 partially overlaps channel stopper 19 in plan view. An opening 20a is formed in field oxide film 20. Opening 20a extends through field oxide film 20. Opening 20a overlaps back gate region 17 in plan view.

Gate insulation film 30 is formed of, for example, silicon oxide. Gate insulation film 30 is formed on main surface 10b located between two source regions 15 adjacent to each other. Gate electrode 40 is formed of, for example, polycrystalline silicon. Gate electrode 40 is formed on gate insulation film 30. Gate electrode 40 is also formed on field oxide film 20. Drain region 14 and source region 15 form a drain region and a source region of a vertical metal oxide semiconductor field effect transistor (MOSFET), respectively. Body region 16 forms a body region of the vertical MOSFET. Epitaxial layer 12 forms a drift region of the vertical MOSFET.

Insulation film 50 is formed over main surface 10b so as to cover field oxide film 20, gate insulation film 30, and gate electrode 40. Insulation film 50 extends to the outer peripheral edge of main surface 10b in plan view and covers the remaining portion of channel stopper 19 that is not covered with field oxide film 20. Insulation film 50 may include a plurality of layers. In the example illustrated in FIGS. 1 to 3, insulation film 50 includes a first layer 51 and a second layer 52 formed on first layer 51. First layer 51 is formed of, for example, boron phosphorous silicate glass (BPSG). Second layer 52 is formed of, for example, silicon oxide containing neither boron nor phosphorus. From another viewpoint, the uppermost layer of the plurality of layers included in insulation film 50 is formed of a material containing neither boron nor phosphorus.

A contact hole 50a, a contact hole 50b, and a contact hole 50c are formed in insulation film 50. Contact hole 50a, contact hole 50b, and contact hole 50c each extend through insulation film 50. Contact hole 50a overlaps source region 15 in plan view. Source region 15 is exposed from contact hole 50a. Contact hole 50b overlaps opening 20a and back gate region 17 in plan view. Back gate region 17 is exposed from contact hole 50b. Contact hole 50c overlaps gate electrode 40 located on field oxide film 20 in plan view. Gate electrode 40 located on field oxide film 20 is exposed from contact hole 50c.

Wiring layer 60 is formed of, for example, aluminum or an aluminum alloy. Wiring layer 60 is formed on insulation film 50 located over cell region 10ba. From another viewpoint, wiring layer 60 does not include a portion formed outside cell region 10ba in plan view. Wiring layer 60 includes a gate wiring 61, a source electrode 62, and a gate pad 63. Gate wiring 61 is located over the outer peripheral edge portion of cell region 10ba in plan view. Source electrode 62 is surrounded by gate wiring 61 in plan view. Gate pad 63 is surrounded by gate wiring 61 and source electrode 62 in plan view and is connected to gate wiring 61.

Although not illustrated, barrier metal is formed between wiring layer 60 and insulation film 50, between wiring layer 60 and silicon carbide substrate 10 (source region 15, back gate region 17), and between wiring layer 60 and gate electrode 40. The barrier metal is, for example, a titanium nitride film, a titanium film, or a stacked film of these.

Gate wiring 61 is also formed in contact hole 50c. Thus, gate wiring 61 is electrically connected to gate electrode 40. Source electrode 62 is also formed in contact hole 50a and contact hole 50b. Thus, source electrode 62 is electrically connected to source region 15 and back gate region 17.

Passivation film 70 is formed of, for example, silicon nitride. Passivation film 70 is formed over insulation film 50 so as to cover wiring layer 60. In plan view, the outer peripheral edge of passivation film 70 is situated away from the outer peripheral edge of main surface 10b. That is, insulation film 50 located in its outer peripheral edge portion is exposed from passivation film 70. In passivation film 70, an opening for exposing source electrode 62 and an opening for exposing gate pad 63 are formed.

Protection film 80 is formed of, for example, polyimide. Protection film 80 is formed over insulation film 50, with passivation film 70 interposed therebetween, so as to cover wiring layer 60. In plan view, the outer peripheral edge of protection film 80 is located inside the outer peripheral edge of passivation film 70. The outer peripheral edge of protection film 80 does not overlap a step portion of insulation film 50. In protection film 80, an opening for exposing source electrode 62 and an opening for exposing gate pad 63 are formed. Drain electrode 90 is formed of, for example, titanium or titanium nitride. Drain electrode 90 is formed on main surface 10a. Drain electrode 90 is electrically connected to drain region 14.

### Method of Manufacturing Semiconductor Device 100

A method of manufacturing semiconductor device 100 is described below.

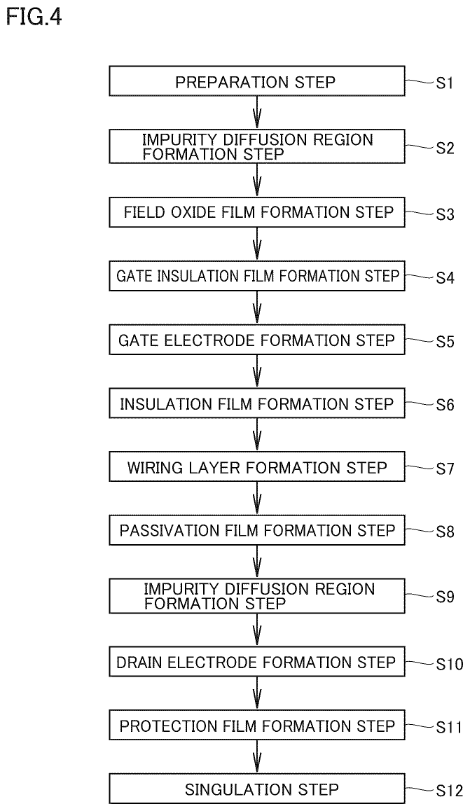

FIG. 4 is a diagram of manufacturing steps of semiconductor device 100. As illustrated in FIG. 4, the method of manufacturing semiconductor device 100 includes a preparation step S1, an impurity diffusion region formation step S2, a field oxide film formation step S3, a gate insulation film formation step S4, a gate electrode formation step S5, an insulation film formation step S6, a wiring layer formation step S7, a passivation film formation step S8, an impurity diffusion region formation step S9, a drain electrode formation step S10, a protection film formation step S11, and a singulation step S12.

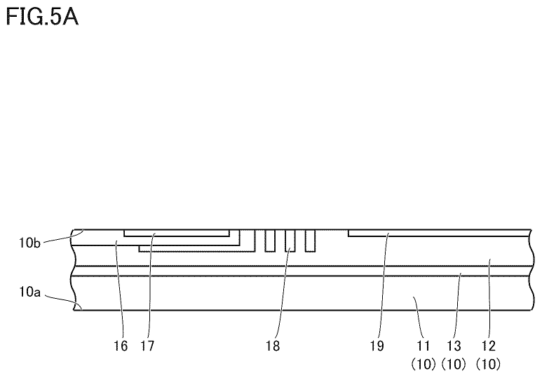

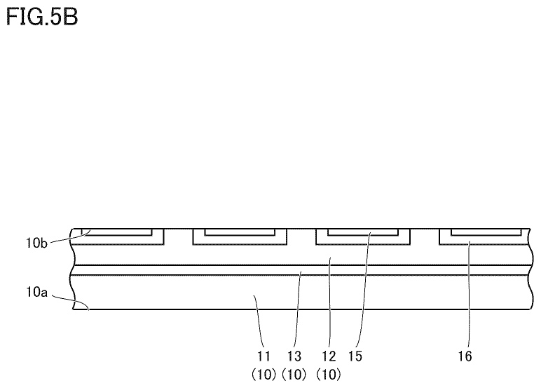

In preparation step S1, silicon carbide substrate 10 is prepared. FIG. 5A is a first cross-sectional view for explaining impurity diffusion region formation step S2. FIG. 5B is a second cross-sectional view for explaining impurity diffusion region formation step S2. As illustrated in FIGS. 5A and 5B, in impurity diffusion region formation step S2, source region 15, body region 16, back gate region 17, guard ring 18, and channel stopper 19 are formed by, for example, performing ion implantation from the main surface 10b side.

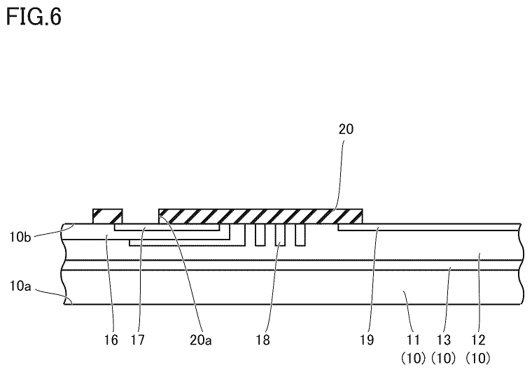

FIG. 6 is a cross-sectional view for explaining field oxide film formation step S3. As illustrated in FIG. 6, in field oxide film formation step S3, field oxide film 20 is formed. In field oxide film formation step S3, firstly, a constituent material of field oxide film 20 is deposited on main surface 10b by, for example, performing tetra ethoxy silane-chemical vapor deposition (TEOS-CVD). Secondly, a resist pattern is formed on the constituent material of field oxide film 20. The resist pattern is formed by applying a photoresist and performing patterning on the photoresist by photolithography. Thirdly, dry etching is performed on the constituent material of field oxide film 20 through an opening of the resist pattern to cause the constituent material of field oxide film 20 to undergo patterning, and field oxide film 20 is formed accordingly.

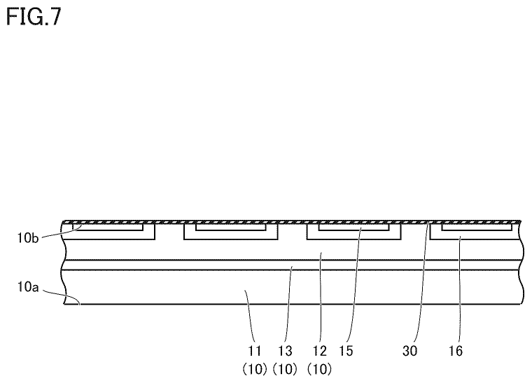

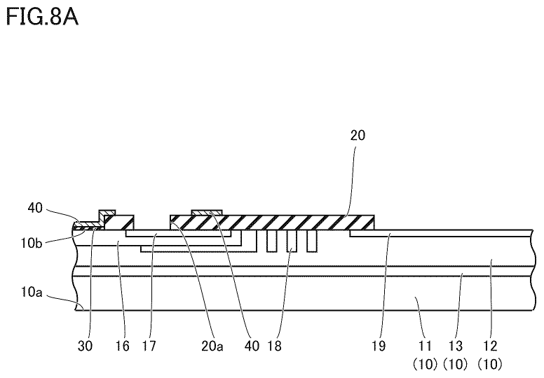

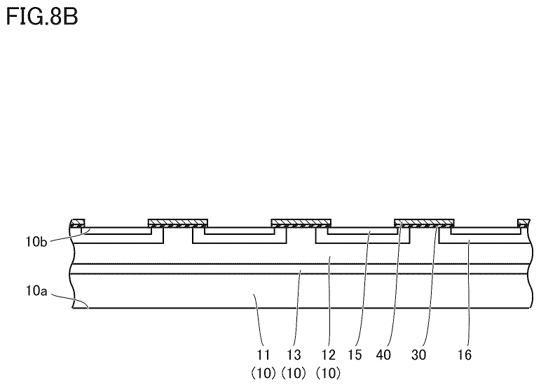

FIG. 7 is a cross-sectional view for explaining gate insulation film formation step S4. As illustrated in FIG. 7, gate insulation film 30 is formed by, for example, performing thermal oxidation on main surface 10b. FIG. 8A is a first cross-sectional view for explaining gate electrode formation step S5. FIG. 8B is a second cross-sectional view for explaining gate electrode formation step S5. As illustrated in FIGS. 8A and 8B, in gate electrode formation step S5, gate electrode 40 is formed. In gate electrode formation step S5, firstly, a constituent material of gate electrode 40 is formed on field oxide film 20 and gate insulation film 30 by, for example, performing CVD. Secondly, a resist pattern is formed on the constituent material of gate electrode 40. Thirdly, dry etching is performed on the constituent material of gate electrode 40 through an opening of the resist pattern to cause the constituent material of gate electrode 40 to undergo patterning, and gate electrode 40 is formed accordingly.

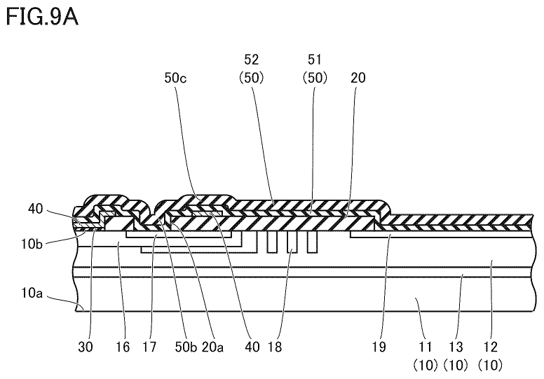

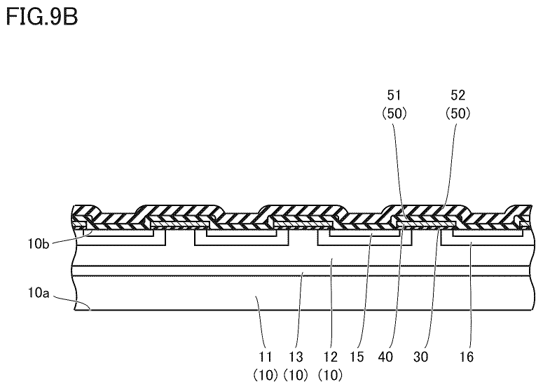

FIG. 9A is a first cross-sectional view for explaining insulation film formation step S6. FIG. 9B is a second cross-sectional view for explaining insulation film formation step S6. As illustrated in FIGS. 9A and 9B, in insulation film formation step S6, insulation film 50 is formed. In insulation film formation step S6, firstly, first layer 51 is formed by CVD for example. Secondly, a constituent material (BPSG) of first layer 51 is caused to flow by performing heat treatment, and first layer 51 is planarized accordingly. Thirdly, second layer 52 is formed by TEOS-CVD for example.

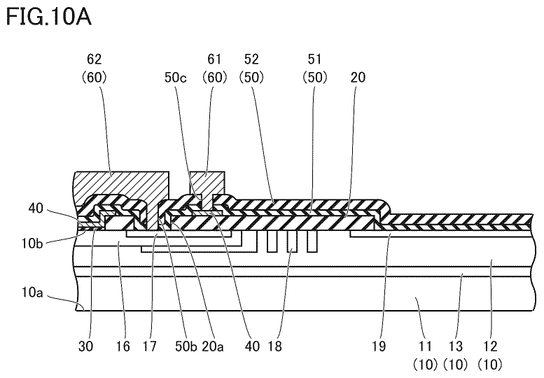

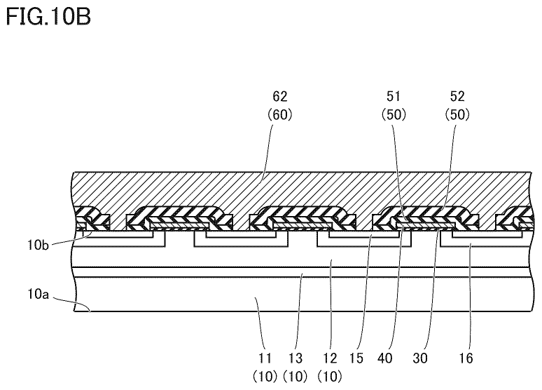

FIG. 10A is a first cross-sectional view for explaining wiring layer formation step S7. FIG. 10B is a second cross-sectional view for explaining wiring layer formation step S7. As illustrated in FIGS. 10A and 10B, in wiring layer formation step S7, wiring layer 60 is formed. In wiring layer formation step S7, contact hole 50a, contact hole 50b, and contact hole 50c are formed by firstly forming a resist pattern on insulation film 50 and secondly performing dry etching on insulation film 50 through an opening of the resist pattern.

Thirdly, barrier metal is formed on insulation film 50, on an inner wall surface of contact hole 50a, on an inner wall surface of contact hole 50b, on an inner wall surface of contact hole 50c, on source region 15 exposed from contact hole 50a, on back gate region 17 exposed from contact hole 50b, and on gate electrode 40 exposed from contact hole 50c by sputtering for example. Fourthly, a constituent material of wiring layer 60 is formed on the barrier metal by sputtering for example. Fifthly, a resist pattern is formed on the constituent material of wiring layer 60. Sixthly, dry etching is performed on the constituent material of wiring layer 60 through an opening of the resist pattern to cause the constituent material of wiring layer 60 and the barrier metal to undergo patterning, and wiring layer 60 is formed accordingly.

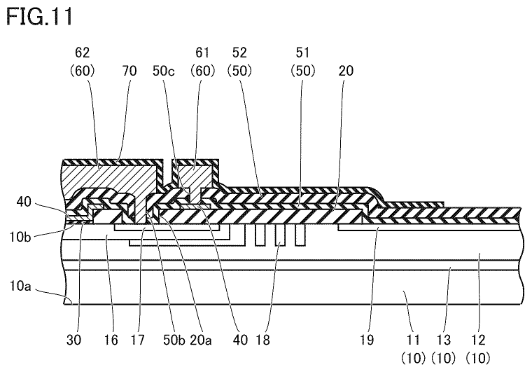

FIG. 11 is a cross-sectional view for explaining passivation film formation step S8. As illustrated in FIG. 11, in passivation film formation step S8, passivation film 70 is formed. In passivation film formation step S8, firstly, a constituent material of passivation film 70 is formed by CVD for example. Secondly, a resist pattern is formed on the constituent material of passivation film 70. Thirdly, dry etching is performed on the constituent material of passivation film 70 through an opening of the resist pattern to cause the constituent material of passivation film 70 to undergo patterning, and passivation film 70 is formed accordingly.

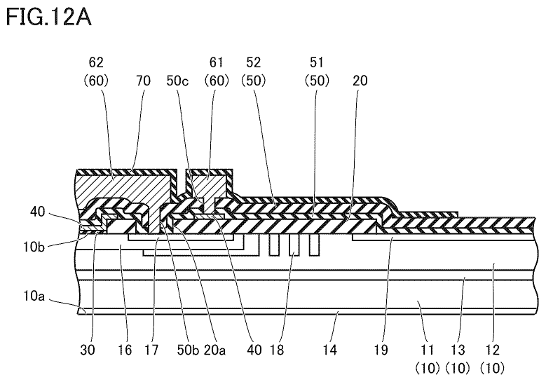

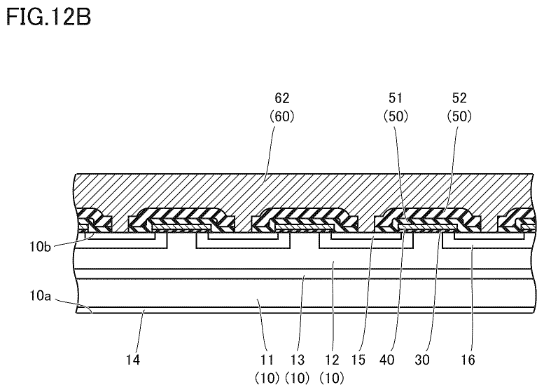

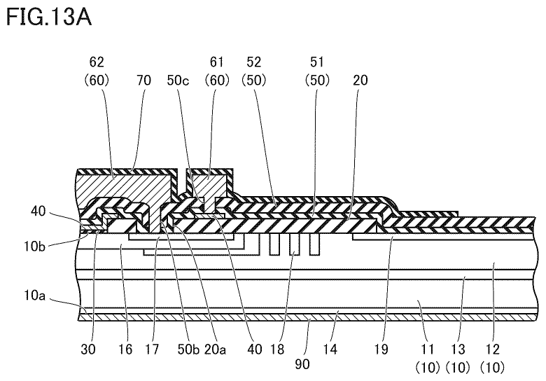

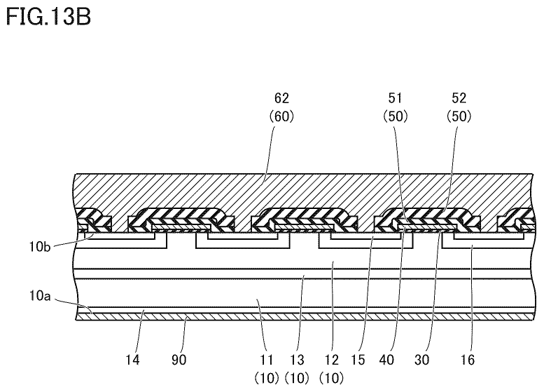

FIG. 12A is a first cross-sectional view for explaining impurity diffusion region formation step S9. FIG. 12B is a second cross-sectional view for explaining impurity diffusion region formation step S9. As illustrated in FIGS. 12A and 12B, in impurity diffusion region formation step S9, drain region 14 is formed by, for example, performing ion implantation from the main surface 10a side. FIG. 13A is a first cross-sectional view for explaining drain electrode formation step S10. FIG. 13B is a second cross-sectional view for explaining drain electrode formation step S10. As illustrated in FIGS. 13A and 13B, drain electrode 90 is formed on main surface 10a by sputtering for example. In protection film formation step S11, protection film 80 is formed by coating passivation film 70 with a constituent material of protection film 80 and hardening the constituent material of protection film 80. In singulation step S12, by cutting silicon carbide substrate 10 and insulation film 50 along a dicing line, a wafer that has undergone the steps up to protection film formation step S11 is separated into a plurality of semiconductor devices 100. As described above, semiconductor device 100 having the configuration illustrated in FIGS. 1 to 3 is obtained.

### Effects of Semiconductor Device 100

Effects of semiconductor device 100 are described below in comparison with a semiconductor device according to a comparative example. The semiconductor device according to the comparative example is referred to as semiconductor device 100A.

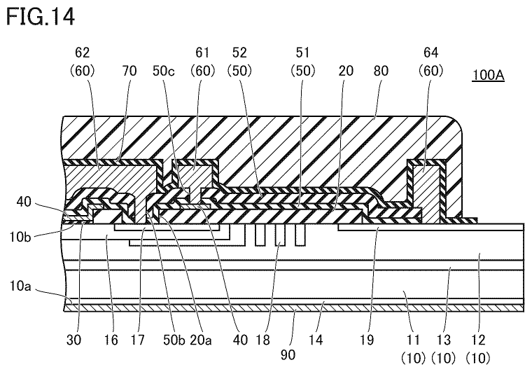

FIG. 14 is a cross-sectional view of semiconductor device 100A. FIG. 14 illustrates a cross section in the position corresponding to II-II in FIG. 1. As illustrated in FIG. 14, in semiconductor device 100A, the outer peripheral edge of an insulation film 50 is situated away from the outer peripheral edge of a main surface 10b in plan view. That is, in semiconductor device 100A, an outer peripheral edge portion of main surface 10b is exposed from insulation film 50. In semiconductor device 100A, a wiring layer 60 includes a portion located outside a termination structure (a plurality of guard rings 18) in plan view. More specifically, in semiconductor device 100A, wiring layer 60 further includes a frame wiring 64. Frame wiring 64 is formed on the outer peripheral edge portion of main surface 10b exposed from insulation film 50 and on an outer peripheral edge portion of insulation film 50, covering these outer peripheral edge portions.

In semiconductor device 100A, frame wiring 64 easily corrodes by reacting with moisture. In particular, a silicon carbide substrate 10 is used in semiconductor device 100A, and thus, an electric field is easily applied to an outer peripheral edge portion of semiconductor device 100A and the corrosion of frame wiring 64 easily progresses due to the electric field. Consequently, a silicon carbide product may be generated from the silicon carbide contained in silicon carbide substrate 10 and the aluminum contained in wiring layer 60 (frame wiring 64), and the THB resistance may decrease due to the product. The silicon carbide product is a corrosion product derived from silicon carbide or silicon oxide generated as a result of corrosion of silicon carbide.

In contrast, in semiconductor device 100, wiring layer 60 is located inside the termination structure in plan view and does not include frame wiring 64. Thus, even if a strong electric field is applied to an outer peripheral edge portion of semiconductor device 100, progress in corrosion of wiring layer 60 and generation of a silicon carbide product are more unlikely to occur and the THB resistance of semiconductor device 100 is ensured.

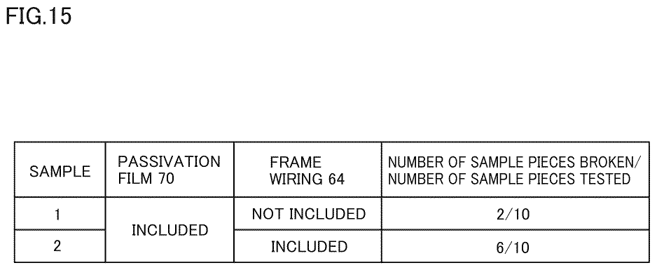

FIG. 15 is a table indicating the results of a THB resistance test. For the THB resistance test, Sample 1 and Sample 2 were prepared. Sample 1 and Sample 2 correspond to semiconductor device 100 and semiconductor device 100A, respectively. That is, frame wiring 64 was included in Sample 2 while frame wiring 64 was not included in Sample 1. Passivation film 70 was included in both Sample 1 and Sample 2. As indicated in FIG. 15, as for Sample 2, dielectric breakdown occurred in six sample pieces out of ten sample pieces while as for Sample 1, dielectric breakdown occurred in only two sample pieces out of ten sample pieces. From this, it was found that the THB resistance was improved by wiring layer 60 not including a portion that is arranged outside the termination structure (the plurality of guard rings 18) in plan view (i.e. by wiring layer 60 not including frame wiring 64).

In semiconductor device 100, insulation film 50 is formed so as to reach the outer peripheral edge of main surface 10b. Thus, when semiconductor device 100 is sealed with mold resin, the mold resin comes into contact with insulation film 50 rather than silicon carbide substrate 10. As a result, according to semiconductor device 100, adhesion between the mold resin and semiconductor device 100 can be enhanced.

A material containing boron or phosphorus has high hygroscopic properties. In semiconductor device 100, however, second layer 52 (the uppermost layer of the plurality of layers included in insulation film 50) is formed of a material containing neither boron nor phosphorus. Thus, according to semiconductor device 100, insulation film 50 is less likely to absorb moisture, and moisture resistance, waterproof performance, and adhesion to the mold resin are increased while corrosion of silicon carbide substrate 10 can be inhibited.

### Variation 1

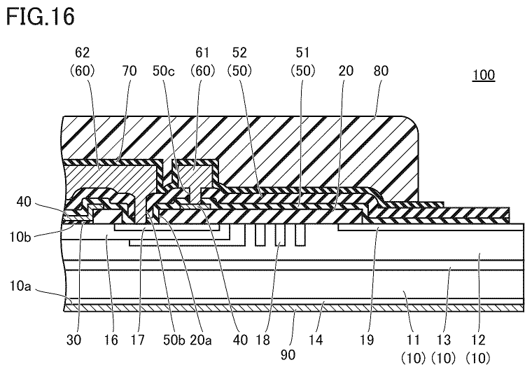

FIG. 16 is a cross-sectional view of semiconductor device 100 according to Variation 1. FIG. 16 illustrates a cross section in the position corresponding to II-II in FIG. 1. An outer peripheral edge portion of silicon carbide substrate 10 in plan view forms part of the dicing line (see singulation step S12). Insulation film 50 is not necessarily required to cover main surface 10b located on the dicing line. From another viewpoint, the outer peripheral edge of insulation film 50 may be located inside the outer peripheral edge of main surface 10b. If insulation film 50 is also formed on main surface 10b located on the dicing line, a crack may develop into insulation film 50 at the time of dicing. Thus, by not covering main surface 10b located on the dicing line with insulation film 50, it is enabled to inhibit such aforementioned development of a crack into insulation film 50 and also enabled to maintain the waterproof performance of insulation film 50.

### Variation 2 and Variation 3

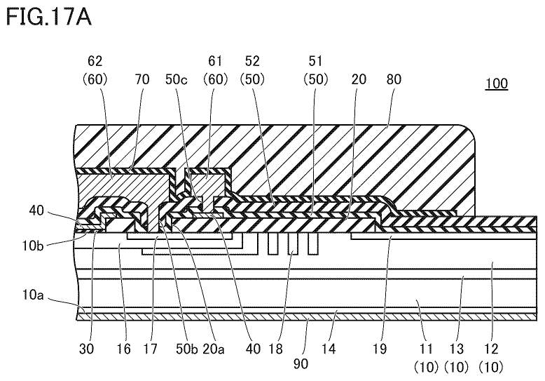

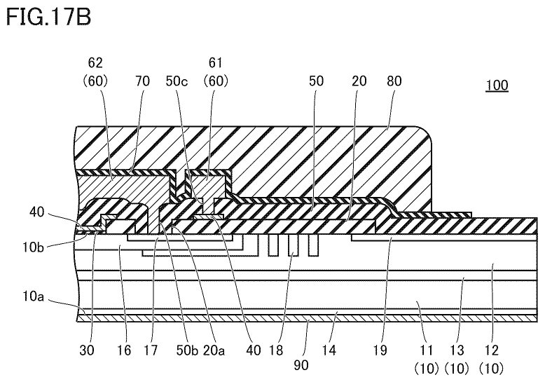

FIG. 17A is a cross-sectional view of semiconductor device 100 according to Variation 2. FIG. 17A illustrates a cross section in the position corresponding to II-II in FIG. 1. As illustrated in FIG. 17A, the outer peripheral edge of protection film 80 may be located outside the outer peripheral edge of passivation film 70 in plan view. In this case, the adhesion between protection film 80 and insulation film 50 is improved by causing the outer peripheral edge of protection film 80 not to overlap the step portion of insulation film 50.

FIG. 17B is a cross-sectional view of semiconductor device 100 according to Variation 3. FIG. 17B illustrates a cross section in the position corresponding to II-II in FIG. 1. As illustrated in FIG. 17B, insulation film 50 is constituted by a single layer and the single layer may be formed of a material (silicon oxide) containing neither boron nor phosphorus.

### Variation 4

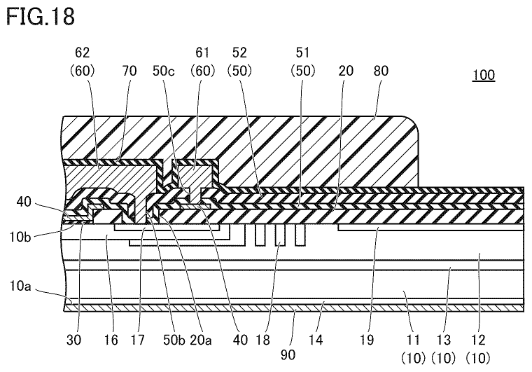

FIG. 18 is a cross-sectional view of semiconductor device 100 according to Variation 4. FIG. 18 illustrates a cross section in the position corresponding to II-II in FIG. 1. As illustrated in FIG. 18, field oxide film 20 may extend so that the outer peripheral edge of field oxide film 20 reaches the outer peripheral edge of main surface 10b in plan view. Field oxide film 20 may be thicker than any of the plurality of layers included in insulation film 50. In this case, field oxide film 20 that is the thickest reaches the outer peripheral edge of main surface 10b, and thus, it is difficult for moisture to come into contact with silicon carbide substrate 10 in a position where a strong electric field is applied during operation of semiconductor device 100. In addition, in this case, even if corrosion occurs, the corrosion stagnates in a distal end portion of field oxide film 20 that is the thickest, and thus, the corrosion can be hindered from progressing to an active cell.

In addition, as a result of field oxide film 20 extending so as to reach the outer peripheral edge of main surface 10b, insulation film 50 and passivation film 70 are each formed flat without including a step portion over outer peripheral region 10bb. Accordingly, in this case, the adhesion of protection film 80 and the adhesion of the mold resin can be enhanced.

### Variation 5

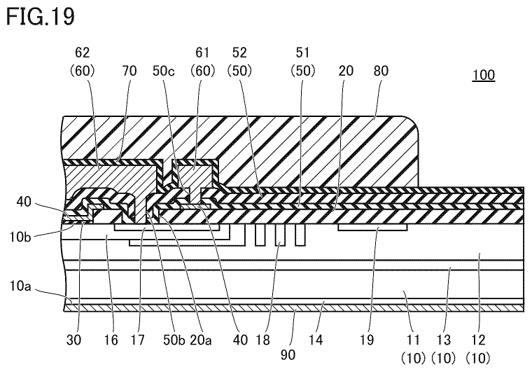

FIG. 19 is a cross-sectional view of semiconductor device 100 according to Variation 5. FIG. 19 illustrates a cross section in the position corresponding to II-II in FIG. 1. As illustrated in FIG. 19, channel stopper 19 is not necessarily required to be formed so as to reach the outer peripheral edge of main surface 10b in plan view. That is, channel stopper 19 may be covered with field oxide film 20. In this case, no interface is present between the mold resin and channel stopper 19. As a result, electron transfer does not occur at the interface between the mold resin and channel stopper 19, and peeling of the mold resin due to a chemical reaction at the interface can be inhibited.

### Variation 6 and Variation 7

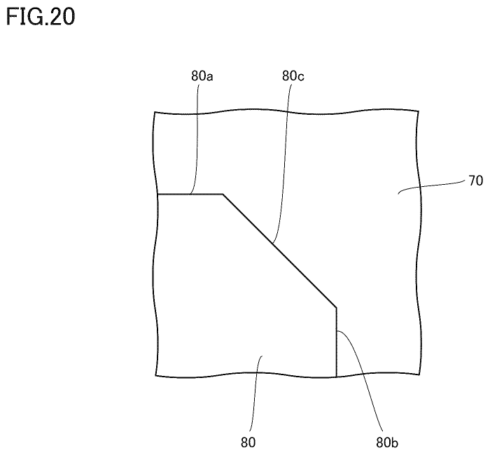

FIG. 20 is an enlarged plan view of semiconductor device 100 according to Variation 6. FIG. 20 illustrates an enlarged plan view in the position corresponding to XX in FIG. 1. As illustrated in FIG. 20, in plan view, a corner portion of the outer peripheral edge of protection film 80 may include a plurality of surfaces. Two adjoining surfaces of the plurality of surfaces that constitute the corner portion of the outer peripheral edge of protection film 80 form an angle larger than 90°. In the example illustrated in FIG. 20, the corner portion of the outer peripheral edge of protection film 80 includes a surface 80a, a surface 80b, and a surface 80c. Surface 80c is contiguous to surface 80a at one end and is contiguous to surface 80b at the other end. The angle formed by surface 80a and surface 80c and the angle formed by surface 80 b and surface 80 c are each larger than 90°.

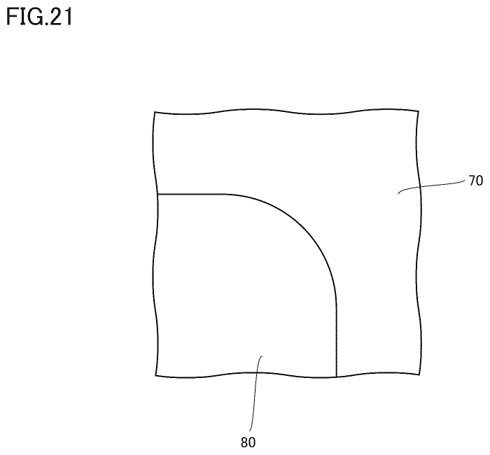

FIG. 21 is an enlarged plan view of semiconductor device 100 according to Variation 7. FIG. 21 illustrates an enlarged plan view in the position corresponding to XX in FIG. 1. As illustrated in FIG. 21, the corner portion of the outer peripheral edge of protection film 80 may have an arc shape in plan view. In the corner portion of the outer peripheral edge of protection film 80, a crack may be caused by thermal stress from the mold resin. In these cases, by chamfering the corner portion of protection film 80 or forming the corner portion of protection film 80 into an arc shape, stress concentration on the corner portion of protection film 80 is alleviated and the aforementioned crack occurrence is inhibited, and water resistance is increased accordingly.

### Variation 8

Although a case where a vertical MOSFET is formed as a semiconductor element in semiconductor device 100 is described above as an example, a power semiconductor element other than the vertical MOSFET, such as a Schottky barrier diode or an insulated gate bipolar transistor (IGBT), may be formed in semiconductor device 100.

### Embodiment 2

In the present embodiment, the semiconductor device according to Embodiment 1 is applied to a power conversion device. Although the present disclosure is not limited to a particular power conversion device, a case where the present disclosure is applied to a three-phase inverter is described below as Embodiment 2.

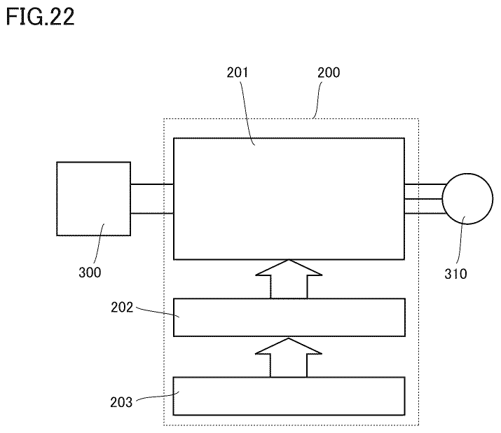

FIG. 22 is a block diagram illustrating a configuration of a power conversion system to which the power conversion device according to Embodiment 2 is applied.

The power conversion system illustrated in FIG. 22 is made up of a power conversion device 200, a power supply 300, and a load 310. Power supply 300 is a direct current (DC) power supply that supplies DC power to power conversion device 200. Power supply 300 can be configured using various types, and can be constituted by, for example, a DC system, a solar battery, or a storage battery or may be constituted by a rectifier circuit or an alternating current (AC)/DC converter connected to an AC system. For another example, power supply 300 may be constituted by a DC/DC converter that converts DC power output from a DC system into predetermined power.

Power conversion device 200 is a three-phase inverter connected between power supply 300 and load 310 and converts the DC power supplied from power supply 300 into AC power to supply the resultant AC power to load 310. As illustrated in FIG. 22, power conversion device 200 includes a main conversion circuit 201 that converts DC power into AC power to output the resultant AC power, and a control circuit 203 that outputs a control signal for controlling main conversion circuit 201 to main conversion circuit 201.

Load 310 is a three-phase electric motor driven with the AC power supplied from power conversion device 200. Load 310 is not limited to a particular application but is an electric motor mounted on various electric apparatuses, and is used as an electric motor for, for example, a hybrid vehicle, an electric vehicle, a railroad vehicle, an elevator, or an air conditioning apparatus.

Power conversion device 200 is described in detail below. Main conversion circuit 201 includes a switching element and a freewheeling diode (not illustrated), and converts DC power supplied from power supply 300 into AC power to supply the resultant AC power to load 310 by the switching element performing switching. Although there are various specific circuit configurations of main conversion circuit 201, main conversion circuit 201 according to Embodiment 1 is a two-level three-phase full-bridge circuit and can be made up of six switching elements and six freewheeling diodes in anti-parallel with the respective switching elements. At least one of each switching element and each freewheeling diode of main conversion circuit 201 is a switching element or a freewheeling diode included in a semiconductor device 202 corresponding to one of the semiconductor devices in Embodiment 1. The six switching elements are connected in series two by two to form upper and lower arms, and each of the upper and lower arms forms each phase (U phase, V phase, W phase) of the full bridge circuit. Respective output terminals of the upper and lower arms, that is, three output terminals of main conversion circuit 201 are connected to load 310.

Main conversion circuit 201 includes a drive circuit (not illustrated) for driving each of the switching elements, and the drive circuit may be arranged in semiconductor device 202 or the drive circuit may be provided separately from semiconductor device 202. The drive circuit generates a drive signal for driving the switching element of main conversion circuit 201 to supply the drive signal to a control electrode of the switching element of main conversion circuit 201. Specifically, in accordance with a control signal from control circuit 203, which is described below, the drive circuit outputs a drive signal for causing the switching element to enter the ON state and a drive signal for causing the switching element to enter the OFF state to the respective control electrodes of the switching elements. When the switching element is maintained in the ON state, the drive signal is a signal of a voltage higher than or equal to a threshold voltage of the switching element (i.e. an ON signal), and when the switching element is maintained in the OFF state, the drive signal is a signal of a voltage lower than or equal to the threshold voltage of the switching element (i.e. an OFF signal).

Control circuit 203 controls the switching elements of main conversion circuit 201 so that desired power is supplied to load 310. Specifically, control circuit 203 calculates time for which each of the switching elements of main conversion circuit 201 is needed to be in the ON state (i.e. ON time) on the basis of the power needed to be supplied to load 310. For example, control circuit 203 can control main conversion circuit 201 through PWM control in which the ON time of the switching element is modulated according to the voltage needed to be output. Further, control circuit 203 outputs a control command (control signal) to the drive circuit included in main conversion circuit 201 so that, at each timing, the ON signal is output to the switching element needed to enter the ON state and the OFF signal is output to the switching element needed to enter the OFF state. In accordance with the control signal, the drive circuit outputs the ON signal or the OFF signal as the drive signal to the control electrode of each of the switching elements.

In the power conversion device according to Embodiment 2, the semiconductor device according to Embodiment 1 (semiconductor device 100) is applied as semiconductor device 202 included in main conversion circuit 201, and thus, the THB resistance of semiconductor device 202 can be secured.

Although an example in which the present disclosure is applied to a two-level three-phase inverter is described in Embodiment 1, the present disclosure is not limited thereto but is applicable to various power conversion devices. Although a two-level power conversion device is employed in Embodiment 1, a three-level or multi-level power conversion device may be employed, and when power is supplied to a single-phase load, the present disclosure may be applied to a single-phase inverter. In addition, when power is supplied to a DC load or the like, the present disclosure is also applicable to a DC/DC converter or an AC/DC converter.

Moreover, the power conversion device to which the present disclosure is applied is not limited to the case where the above-described load is an electric motor but can be used as, for example, a power supply device of an electric discharge machine, a laser machine, an induction heating cooker, or a non-contact power supply system, or can further be used as a power conditioner of a photovoltaic power generation system, a power storage system, or the like.

### APPENDICES

Aspects of the present disclosure are described as appendices, collectively.

### Appendix 1

A semiconductor device comprising:
a silicon carbide substrate;
a field oxide film;
an insulation film; and
a wiring layer, wherein
the silicon carbide substrate includes a first main surface, and a second main surface being an opposite surface of the first main surface,
the second main surface includes a cell region, and an outer peripheral region located between the cell region and an outer peripheral edge of the second main surface in plan view,
the silicon carbide substrate includes a termination structure and a channel stopper that are formed in the second main surface located in the outer peripheral region in the silicon carbide substrate,
the channel stopper is located outside the termination structure in plan view,
a conductivity type of the silicon carbide substrate and a conductivity type of the channel stopper are each a first conductivity type,
the termination structure has a second conductivity type opposite to the first conductivity type,
the field oxide film is formed on the second main surface located in the outer peripheral region so as to overlap the termination structure in plan view and at least partially overlap the channel stopper in plan view,
the insulation film is formed over the second main surface so as to cover the field oxide film, and
the wiring layer is formed on the insulation film so as to be located inside the termination structure in plan view.

### Appendix 2

The semiconductor device according to Appendix 1, wherein an outer peripheral edge of the insulation film is located inside the outer peripheral edge of the second main surface in plan view.

### Appendix 3

The semiconductor device according to Appendix 1 or 2, wherein the insulation film is formed of a material containing neither boron nor phosphorus.

### Appendix 4

The semiconductor device according to Appendix 1 or 2, wherein
the insulation film includes a plurality of layers stacked,
the insulation film extends so as to reach the outer peripheral edge of the second main surface in plan view, and
an uppermost layer of the plurality of layers is formed of a material containing neither boron nor phosphorus.

### Appendix 5

The semiconductor device according to any one of Appendices 1 to 4, further comprising
a protection film, wherein
the protection film is formed over the insulation film so that an outer peripheral edge of the protection film does not overlap a step portion of the insulation film in plan view.

### Appendix 6

The semiconductor device according to Appendix 1, wherein
the insulation film includes a plurality of layers stacked,
the field oxide film is thicker than any of the plurality of layers, and
the field oxide film extends so as to reach the outer peripheral edge of the second main surface in plan view.

### Appendix 7

The semiconductor device according to Appendix 1, wherein the field oxide film is formed on the second main surface so as to cover the channel stopper.

### Appendix 8

The semiconductor device according to any one of Appendices 1 to 7, further comprising
a protection film, wherein
the protection film is formed over the insulation film,
in plan view, a corner portion of an outer peripheral edge of the protection film includes a plurality of surfaces, and
an angle between two adjoining surfaces of the plurality of surfaces is larger than 90°.

### Appendix 9

The semiconductor device according to any one of Appendices 1 to 7, further comprising
a protection film, wherein
the protection film is formed over the insulation film, and
in plan view, a corner portion of an outer peripheral edge of the protection film has an arc shape.

### Appendix 10

A power conversion device comprising:
a main conversion circuit to convert input power to output the input power, the main conversion circuit including the semiconductor device according to any one of Appendices 1 to 9;
a drive circuit to output a drive signal for driving the semiconductor device to the semiconductor device; and
a control circuit to output a control signal for controlling the drive circuit to the drive circuit.

Although the embodiments of the present invention have been described, it should be understood that the herein-disclosed embodiments are presented by way of illustration and example in all respects and are not to be taken by way of limitation. The scope of the present invention is defined by the claims and intended to include any changes within the purport and scope equivalent to the claims.

What is claimed is:

1. A semiconductor device comprising:
a silicon carbide substrate;
a field oxide film;
an insulation film; and
a wiring layer, wherein
the silicon carbide substrate includes a first main surface, and a second main surface being an opposite surface of the first main surface,
the second main surface includes a cell region, and an outer peripheral region located between the cell region and an outer peripheral edge of the second main surface in plan view,
the silicon carbide substrate includes a termination structure and a channel stopper that are formed in the second main surface located in the outer peripheral region in the silicon carbide substrate,
the channel stopper is located outside the termination structure in plan view,
a conductivity type of the silicon carbide substrate and a conductivity type of the channel stopper are each a first conductivity type,
the termination structure has a second conductivity type opposite to the first conductivity type,
the field oxide film is formed on the second main surface located in the outer peripheral region so as to overlap the termination structure in plan view and at least partially overlap the channel stopper in plan view,
the insulation film is formed over the second main surface so as to cover the field oxide film, and
the wiring layer is formed on the insulation film so as to be located inside the termination structure in plan view.

2. The semiconductor device according to claim 1, wherein an outer peripheral edge of the insulation film is located inside the outer peripheral edge of the second main surface in plan view.

3. The semiconductor device according to claim 1, wherein the insulation film is formed of a material containing neither boron nor phosphorus.

4. The semiconductor device according to claim 1, wherein
the insulation film includes a plurality of layers stacked,
the insulation film extends so as to reach the outer peripheral edge of the second main surface in plan view, and
an uppermost layer of the plurality of layers is formed of a material containing neither boron nor phosphorus.

5. The semiconductor device according to claim 1, further comprising
a protection film, wherein
the protection film is formed over the insulation film so that an outer peripheral edge of the protection film does not overlap a step portion of the insulation film in plan view.

6. The semiconductor device according to claim 1, wherein
the insulation film includes a plurality of layers stacked,
the field oxide film is thicker than any of the plurality of layers, and
the field oxide film extends so as to reach the outer peripheral edge of the second main surface in plan view.

7. The semiconductor device according to claim 1, wherein the field oxide film is formed on the second main surface so as to cover the channel stopper.

8. The semiconductor device according to claim 1, further comprising
a protection film, wherein
the protection film is formed over the insulation film,
in plan view, a corner portion of an outer peripheral edge of the protection film includes a plurality of surfaces, and
an angle between two adjoining surfaces of the plurality of surfaces is larger than 90°.

9. The semiconductor device according to claim 1, further comprising
a protection film, wherein
the protection film is formed over the insulation film, and
in plan view, a corner portion of an outer peripheral edge of the protection film has an arc shape.

10. A power conversion device comprising:
a main conversion circuit to convert input power to output the input power, the main conversion circuit including the semiconductor device according to claim 1;
a drive circuit to output a drive signal for driving the semiconductor device to the semiconductor device; and
a control circuit to output a control signal for controlling the drive circuit to the drive circuit.
